(19) United States
(12) Patent Application Publication
(10) Pub. No.: US 2023/0058294 A1
(43) Pub. Date: Feb. 23, 2023

(54) CONDITION-BASED CIRCUIT BREAKER MAINTENANCE ARRANGEMENT FOR ELECTRICAL POWER DISTRIBUTION INFRASTRUCTURE

(71) Applicant: Alabama Power Company, Birmingham, AL (US)

(72) Inventors: Erik BIERBRAUER, Birmingham, AL (US); Richard SCHNEIDER, Birmingham, AL (US); Glenn R. Wilson, Birmingham, AL (US)

(21) Appl. No.: 17/407,976

(22) Filed: Aug. 20, 2021

(51) Int. Cl. H02J 13/00

(52) U.S. Cl. CPC H02J 13/0004; H02J 13/00002; H02J 13/00034

(57) ABSTRACT

A computer-automated maintaining of circuit breakers in a power distribution infrastructure based upon operating conditions recorded during breaker events of particular identified circuit breakers is described herein. The breaker event data sets are accumulated initially by file servers in a variety of formats. A parser performs an automated parsing of the breaker event data sets to render breaker event records that are thereafter stored in a central data repository. Maintenance engines apply data analysis and decision logic to particular event records for particular identified circuit breakers obtained from the central data repository and issue requests for actions to be taken with respect to the particular identified circuit breakers based upon operating conditions experienced by the particular identified circuit breakers.

### FIELD OF THE INVENTION

This invention relates generally to the field of electrical power distribution systems. More particularly, the invention is directed to maintaining circuit breakers of substations within an electrical power distribution infrastructure. Even more particularly, the invention is directed to a networked circuit breaker event data acquisition and processing arrangement for parsing/tabling data point sets (provided in a variety of file formats) relating to circuit breaker events occurring at electrical substations, applying pre-configured decision logic to the tabled data point sets to establish a current physical condition of particular circuit breaker components, and issuing proactive/reactive maintenance instructions/alerts according to the determined current physical condition of the circuit breaker components.

### BACKGROUND OF THE INVENTION

Substations are critical components of electrical grids. Substations perform, among other things, an operation of transforming voltage at an input level to another voltage level as the power passes through the substation while being transported through an electrical power transmission system. See e.g. FIG. 1 (described herein below). Typically, output voltage of a substation is lower than input voltage as power makes its way, via substations, from a very high voltage output at a generating facility to a substantially lower voltage for power ultimately provided to residential customers. Additionally, substations may carry out: switching flow of electrical power, providing a point of electrical interconnection to a third party, and providing voltage regulation.

In terms of monetary value and criticality of function, circuit breakers are usually considered the second most critical type of substation component (transformers being the most). Digital breaker controllers respond to detection of hazardous current or voltage conditions (such as a lightning strike) that might damage other substation assets by interrupting power flow as quickly as possible by activating a circuit breaker to interrupt the flow of electricity in the circuit. The circuit breakers are re-set (restoring power transmission at the substation) upon determining that it is safe to restore power flow through the substation/breaker.

Historically, the digital breaker controllers (also referred to as digital protective relays) have been able to locally capture and store condition data associated with breaker events. Digital breaker controllers of various vendors, models and model versions store the data in a multitude of non-standard ways. As a consequence, centralized decision-making has relied primarily on duration of service, as opposed to observed conditions and events, when carrying out maintenance decision making for circuit breakers that have not yet failed. This approach to substation maintenance leads to excessive maintenance resources being expended to perform unnecessary health status checkups for substations that have not been subject to circuit breaker conditions/events and therefore are not in need of repair, reconditioning or replacement.

### SUMMARY OF THE INVENTION

Illustrative examples of the invention are used to provide a method and a computer system configuration facilitating and performing operations for acquisition and processing of breaker event data sets and rendering circuit breaker related service requests and alerts. More particularly, a system and method are disclosed herein that facilitate maintaining circuit breakers in an electrical power distribution infrastructure based upon recorded operating conditions during breaker trip events of particularly identified circuit breakers. The method carried out by the disclosed system includes generating breaker event data set files comprising operating conditions recorded by associated digital protective relays, on an individual circuit breaker basis, during circuit breaker trip events by identified circuit breakers. The system is further configured to perform, in accordance with the method, parsing the breaker event data set files to render breaker event records that are: maintained in a standardized breaker event record format, and comprise operating conditions recorded by associated digital protective relays during breaker events. The method of the configured system further includes tabling the breaker event records in a data repository. The method further includes executing a query upon the data repository to retrieve particular breaker event field data from breaker event records in the data repository corresponding to an identified circuit breaker; and rendering a circuit breaker maintenance request for the identified circuit breaker in accordance with executing circuit breaker logic for performing an analysis of breaker event field data acquired from breaker event records corresponding to the identified circuit breaker during the executing a query.

### BRIEF DESCRIPTION OF THE DRAWINGS

While the appended claims set forth the aspects of the present invention with particularity, the invention and its advantages are best understood from the following detailed description taken in conjunction with the accompanying drawings, of which:

FIG. 1 is a schematic diagram illustrating an electrical power generation and distribution infrastructure;

FIGS. 2A and 2B are schematic functional block diagrams identifying exemplary digital protective relay/circuit breaker configurations in substations of an electrical power generation and distribution infrastructure in accordance with the disclosure;

FIG. 3 is an exemplary network arrangement for generating, processing and analyzing circuit breaker event data sets for performing proactive/reactive maintenance tasks for particular circuit breakers based upon operation conditions to which the particular circuit breakers are exposed, in accordance with the current disclosure;

FIG. 4A is a summary of a set of fields of an exemplary breaker event record for a particular identified circuit breaker in accordance with the current disclosure;

FIG. 4B is a summary of a set of exemplary fields for a wear curve set points record for performing percent-of-wear impact analyses for identified circuit breakers in accordance with the current disclosure;

FIG. 4C is a summary of a set of fields of an exemplary custom breaker trip time limits record for an identified circuit breaker in accordance with the current disclosure;

FIG. 5 is a flowchart summarizing operation of the system illustratively depicted in FIG. 3 to carry out an automated operating conditions-based maintenance of circuit breakers in an electrical distribution infrastructure in accordance with the current disclosure;

FIG. 6 is a flowchart summarizing a set of steps for selectively updating a central data repository by populating fields of a new circuit breaker event record with parsed breaker event data;

FIG. 7 is a chart representing an exemplary wear curve for calculating a remaining life for a circuit breaker, based upon incremental wear associated with recorded breaker events for specifically identified circuit breakers;

FIG. 8A is a flowchart summarizing operation of a reactive maintenance engine that issues requests and notifications with regard to maintenance operations that need relatively urgent/prompt attention to avoid/address a circuit breaker malfunction in accordance with processing alerts arising from processing parsed/tabled breaker events in accordance with the present disclosure; and

FIG. 8B is a flowchart summarizing operations of a proactive maintenance engine that issues maintenance-related requests and notifications with regard to maintenance operations that need relatively less urgent/prompt attention to maintain reliable/expected circuit breaker operation and thereby avoid rushed response to prevent a circuit breaker malfunction in accordance with processing alerts arising from processing parsed/tabled breaker events in accordance with the present disclosure.

### DETAILED DESCRIPTION OF THE DRAWINGS

Illustrative examples of the invention described herein acquire and process a combination of files containing electrical circuit breaker event data point sets, from a multiplicity of digital breaker controllers (digital protective relays) to render, from a centralized remote monitoring and administration center, performance information that is subsequently evaluated to determine a health status of circuit breakers on an individual circuit breaker basis, and further provide alerts/requests to maintenance personnel indicating an action needing to be performed on a particular identified circuit breaker needing remedial maintenance/repair operations.

An infrastructure and related automated condition-based electrical circuit breaker (breaker) maintenance process are described herein. The system is configured to consolidate and maintain, in a central repository, event data files relating to breaker events generated by substation digital relay controllers for substation circuit breakers. After initially acquiring the event data files, the system parses the files to extract data relating to conditions recorded at the particular substations during the operational events. The resulting parsed data is tabled in a database to facilitate performing a variety of queries and analyses of the tabled event data for carrying out proactive/reactive repair/replacement/maintenance operations on particular identified circuit breakers in accordance with the analyzed breaker event data—i.e., on a conditional basis.

Based upon an analysis of the query results, preconfigured breaker maintenance logic generates alerts/requests on a configured basis to carry out both proactive and reactive maintenance of the breakers. For example, the breaker maintenance logic performs calculations and analysis on each event data record acquired from the database to produce detailed breaker status metrics. If any of the metrics are found to be out of limits, an automated alert is sent (e.g., issued in the form of a job ticket to automated maintenance controllers and/or breaker maintenance personnel). The job ticket summarizes a breaker health status requiring remediation and, optionally indicating a remedial action. Additionally, proactive maintenance messages may also be generated (e.g. a remaining time-of-life status) to facilitate preventive maintenance, planning and management of parts replacement and repair operations scheduling. Analysis of event conditions during recorded events facilitates addressing issues (e.g. product defects, shorter/longer than expected lifespans) before an actual failure and/or end-of-life status is reached for a breaker.

The automated data acquisition and processing operations, including application of particularized parsing operations that render uniform data records from a variety of source data file formats, has the potential to increase the effectiveness of substation maintenance by facilitating automated analysis of vast quantities of conditional (event) data for identified breakers that, in turn, enable responding to breaker problems proactively or in near real time rather than relying on predetermined time-based inspection schedules that neither respond to actual observed events during the lifetime of a breaker or manufacturing defects that may result in deviations from expected lifespans of individual breakers.

The system and method described herein facilitate performing queries upon a standardized record format maintained in a centralized database to carry out operations and decision logic to identify and analyze, in an automated manner, circuit breaker trip event data sets associated with particular identified circuit breakers in a power distribution infrastructure. The analysis of breaker events facilitate performing a conditions-based approach to circuit breaker health status—as opposed to a time-based approach where circuit breakers are physically inspected based upon a maintenance schedule regardless of actual operating conditions experienced by the circuit breakers. As a result of the analysis, the system executes further operations to issue proactive/reactive/remedial requests (i.e. job tickets) based upon detected health status changes to particular identified circuit breakers determined based upon actual operating conditions experienced by the particular identified circuit breakers. Such health status changes may occur, for example, as a result of a change to a physical circuit breaker configuration, such as loss of lubrication, physical deterioration of conductive connections/leads arising from arcing and heat generation resulting therefrom. Such identification of physical circuit breaker health status changes and issuance of remedial actions to be taken to ensure proper operation/health of circuit breakers within the distribution infrastructure are carried out in a fully automated manner.

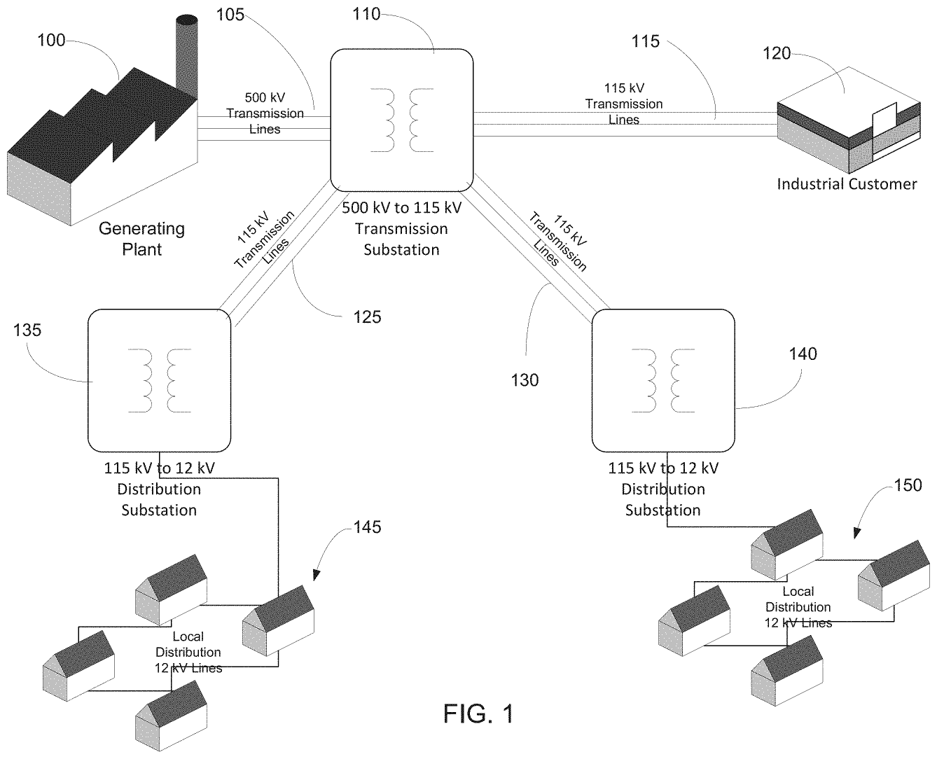

Turning to FIG. 1, an illustrative schematic drawing provides an exemplary distribution system for electrical power originating from a generating plant 100. By way of example, electrical power initially passes via high voltage lines 105 to a high voltage substation 110 including a transformer unit that converts power from a high input level (e.g., 500 kVolts) to an intermediate voltage level (e.g. 115 kVolts). Electrical power passes from the high voltage substation 110 via intermediate voltage lines 115 to an industrial power consumer 120 (e.g. a factory). Other intermediate voltage lines 125 and 130 transport electrical power at the intermediate level (e.g. 115 kVolts) to a first lower voltage substation 135 and a second lower voltage substation 140, respectively. The lower voltage substations 135 and 140 transform the received electricity to still lower voltages (e.g. 12 kVolts). The lower voltage (e.g. 12 kVolts) output from substations 135 and 140 flows via local distribution lines 145 and 150 to still other transformers (not housed in substations) that convert the voltage to a level that is consumable by local residential customers. It will be appreciated that, while only three substations are shown in the highly simplified arrangement depicted in FIG. 1, a typical distribution network includes hundreds of substations.

The illustrative example of FIG. 1 is provided to illustratively depict a typical role of substations in an electrical power distribution infrastructure (electrical grid). More particularly, a plurality of substations are provided in an electrical distribution arrangement to transform voltage, from a very high voltage output of a generating plant, to medium and low voltages for consumption by industrial plants (medium) and private residences (low). Circuit breakers are incorporated into the substations to protect downstream electrical equipment from upstream power surges and/or voltage spikes arising, for example, from lightning strikes. The present disclosure applies to circuit breakers used at any level of an electrical power distribution infrastructure.

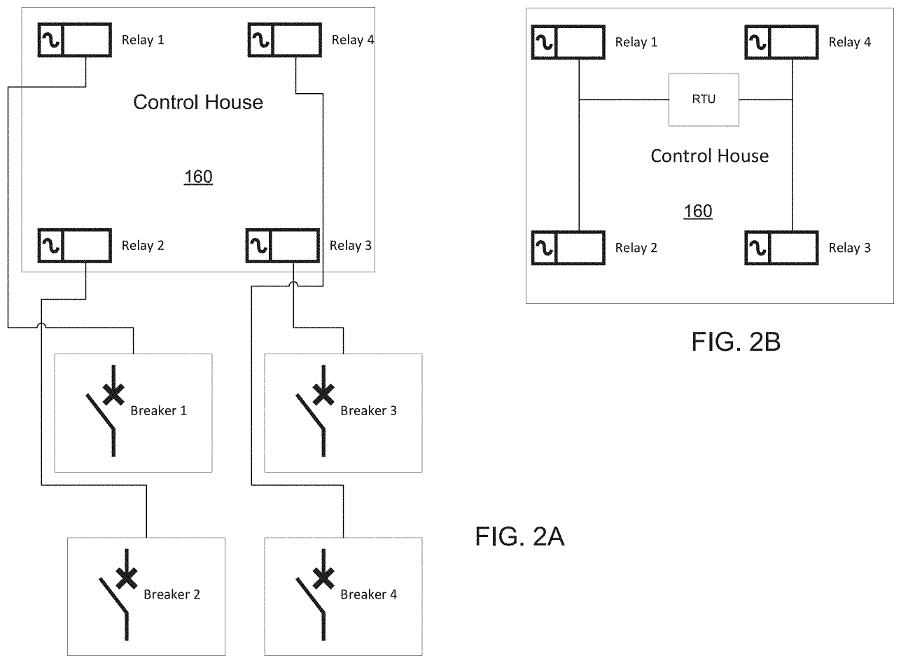

Turning to FIGS. 2A and 2B, schematic diagrams are provided that show a number of configurations for combinations of digital protective relays within a control house of a substation (e.g. substation 135 of FIG. 1). Referring to FIG. 2A, a schematic diagram depicts a control house 160 containing a set of independently operating digital protective relays (relays 1, 2, 3 and 4) coupled to (and controlling) corresponding circuit breakers (breakers 1, 2, 3 and 4).

With continued reference to FIG. 2A, the digital protective relays within the control house 160 execute configured operations (both data acquisition and control) to monitor electrical conditions at a substation for fault conditions (e.g., power surges and voltage spikes). A digital protective relay, in accordance with detecting a fault condition, causes a corresponding circuit breaker to interrupt current passing through the circuit breaker (i.e. trips the circuit breaker) to protect substation equipment from high voltage/current associated with the detected fault condition. A circuit breaker trip operation is referred to herein as a “breaker event.” Digital protective relays, which date back to the 1980, have replaced most of older (electromechanical) style relays. The absence of a standard, the existence of several sources, and the development of several versions/releases of digital protective relays over decades of their incorporation into substation control houses has resulted in a wide variety of information sets (e.g., detected/captured status parameters during a circuit breaker event) and formats for storing/providing data associated with breaker events detected by digital protective relays.

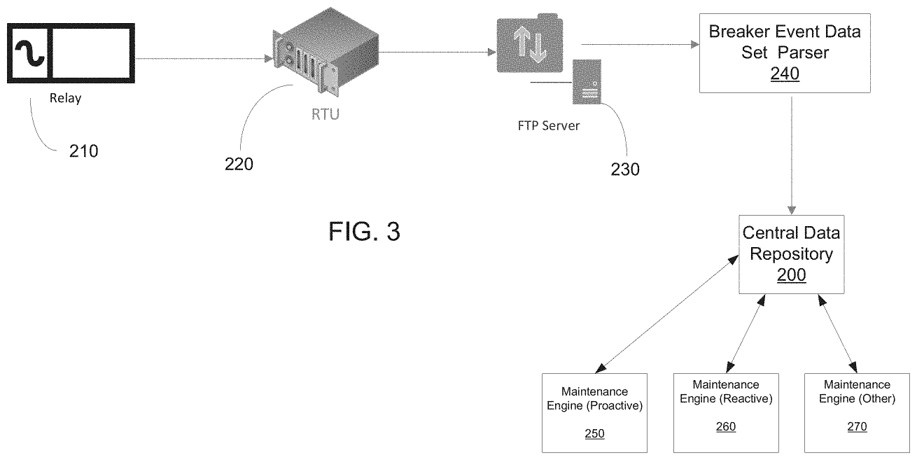

With brief reference to FIG. 2B, two alternative arrangements for supervisory management and control of the plurality of relays (relays 1, 2, 3 and 4) within the control house 160 are provided. In the example of FIG. 2B, a remote terminal unit (RTU) 170 is coupled to each one of the relays. The control schemes depicted in FIG. 2B facilitate coordinating operation of multiple relays as a group to control multiple breakers at a substation simultaneously based on configured logic of the RTU 170. The RTU 170 is further configured to maintain and provide breaker event data sets (e.g. files). Moreover, the RTU 170 are, in turn, configured to operate as remotely accessible data access points within a communication network, to provide the breaker event data sets, via network connections, to a central repository that is discussed further herein below with reference to FIG. 3.

Turning to FIG. 3, an illustrative example of a data transmission path is provided for transport of raw data sets (provided in a variety of formats within files) to a central data repository 200. Breaker event data sets are initially acquired by a digital protective relay 210. The digital protective relay 210 transmits the acquired breaker event data to an RTU unit 220 at a substation. Such transfer by the digital protective relay 210 occurs under polling by the RTU unit 220 (or alternatively/additionally via pushed transmissions in response to detected emergency conditions). The RTU unit 220, by way of example, polls associated relays and forwards the acquired breaker event data to an input/output (data collection) server 230 in response to a received command/request issued by the data collection server 230. The data collection server 230 executes file transfer protocol (FTP) to facilitate transfer/storage of the accumulated breaker event data sets in file format for further processing (e.g., parsing and tabling within the central data repository 200) in accordance with the current disclosure. By way of example, the data collection server 230 stores breaker event files in a directory structure. The directory structure, by way of example, is organized by year (at a highest level), then month, and (at a lower/lowest level) by files having a file name indicating (among other things) a data source (e.g. substation identification, relay identification, etc.).

Digital protective relays (provided/installed over several decades) within a single enterprise comprise a vast variety of sources (makers), models and versions/releases that have applications outside of just substation breaker control. Some digital protective relays are configured to monitor conditions on a transmission or distribution line, while other digital protective relays are associated with a transformer bank. The format of data content within the stored files can be in any of a vast variety of forms supported by the vast variety of data sources, manufacturers, models, and versions of protective digital relays (and circuit breakers) installed within an enterprise over potentially several decades. The present disclosure describes particular features and technical solutions relating to acquisition and automated processing of thousands, tens of thousands, hundreds of thousands, and even millions of event datasets relating to circuit breakers operating under control of digital protective relays. However, the present disclosure is potentially applicable to a variety of automated data parsing arrangements that close an open segment in an automated event data and reactive/proactive maintenance facility that issues requests to carry out associated maintenance and repair operations to maintain an infrastructure for an enterprise—such as an electricity distribution infrastructure of the currently disclosed illustrative example.

Moreover, circuit breaker events occur relatively frequently in a typical power generation enterprise. Thus, the quantity of data sets (e.g. tens of thousands) that are stored/accessed for analysis preclude manual retrieval and formatting. An automated system is provided to retrieve and format acquired data sets within a standardized data record/table form to facilitate a condition-based (as opposed to time-in-use) approach to maintaining/servicing circuit breaker hardware maintained at hundreds—even thousands—of locations in an electrical distribution infrastructure of a power generation/distribution enterprise. Thus, in accordance with the present disclosure, a breaker event data set parser 240 is introduced to carry out, in an automated manner, extracting data content of the files stored in the data collection server 230 and tabling the parsed data on the central data repository 200 within a plurality of tables, in standardized record formats, in accordance with a configured breaker event data storage scheme.

The central data repository 200 is an enterprise server providing file access by a variety of breaker event data consumers within a company seeking to use the tabled breaker event data. In accordance with the current disclosure, the standardized format data is accessed/analyzed by a variety of circuit breaker maintenance components including, by way of example, a proactive maintenance engine 250, a reactive maintenance engine 260, and other maintenance engine 270 (i.e., any other type of maintenance engine—including engines providing long term analysis “machine learning” to re-configure the logic and/or limits of the proactive maintenance engine 250 and/or reactive maintenance engine. Such tasks may include, for example, identifying actual circuit breaker wear that is used to inform/revise wear schedules/charts for circuit breakers in a largely—if not fully-automated management infrastructure. Thus, a system and method are disclosed for carrying out determining status of circuit breaker hardware and carry out proactive/reactive maintenance operations based upon an analyses of operating conditions experienced by particular identified circuit breakers, wherein generation of a database of breaker event records and analysis thereof is performed in an automated/closed-loop circuit breaker health status monitoring/maintenance arrangement and manner.

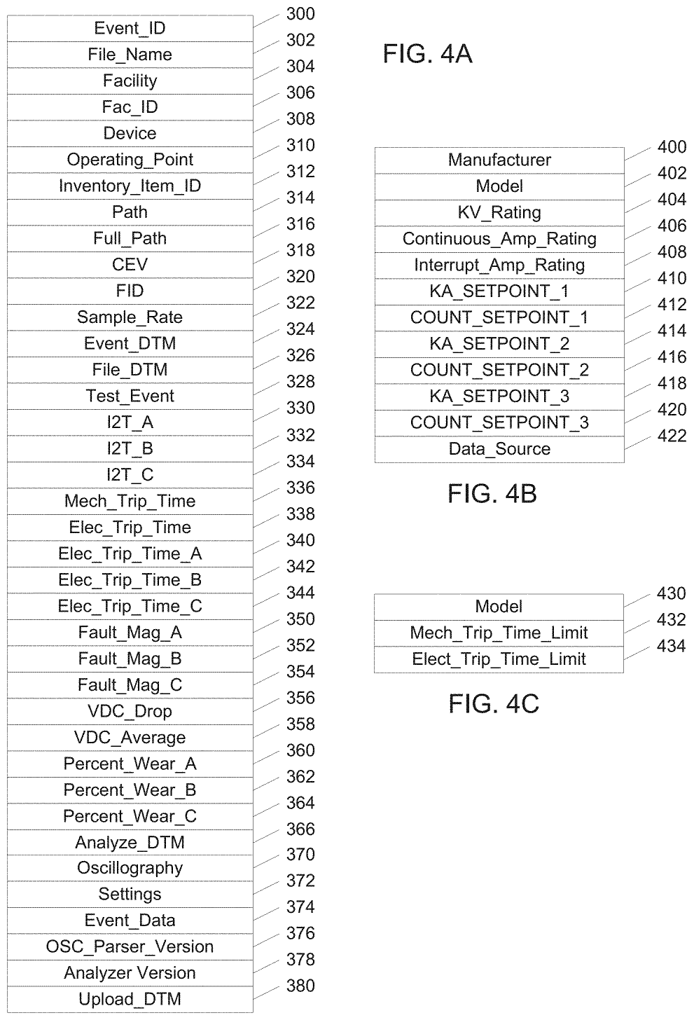

An illustrative example of a parsed data storage scheme for breaker event data stored on the central data repository 200 is provided in FIGS. 4A, 4B and 4C described herein below. The fields having values containing primary search keys for queries to stored tables are identified as “primary key” values. Turning to FIG. 4A an illustrative set of fields of an exemplary record/table structure are provided for use in storing parsed breaker event data sets for the system described herein. An EVENT_ID 300 contains a (primary key) value assigned from an increasing sequence as an event record for a breaker event is added to the table. A FILE_NAME 302 contains a file name and extension of the parsed event file. A FACILITY 304 contains a name of a substation. By way of example, the substation name is extracted by the parser 240 from a file name from which the event data was extracted. FAC_ID 306 contains a (primary key) value (facility ID) extracted from an asset management database and copied to the event record for convenient reference. A DEVICE 308 contains a relay model identification. By way of example, the relay model identification is extracted by the parser 240 from a file name from which the event data was extracted. An OPERATING_POINT 310 contains a string identifying a breaker operating point (also extracted from the file name). An INVENTORY_ITEM_ID 312 contains a (primary key) value identifying the specific breaker equipment associated with the breaker event—extracted from the asset management database and copied to the event record at the time of creating the event record. The breaker identification value (stored in the INVENTORY_ITEM_ID 312), by way of a particular example, is obtained by querying an asset management database (see example record fields for such database in FIG. 4B) by searching for a breaker equipment record including the combination of: (1) substation identification and (2) breaker operating point number—both of which are derived from the source breaker event file. These two pieces of information are merely one example of using information within a breaker event data set file to identify a particular circuit breaker with which the breaker event data is associated.

A PATH 314 contains a string identifying a directory path of the file (stored on the data collection server) from which the event record was extracted. A FULL_PATH 316 contains a string identifying the directory path of the PATH 314 and a name of the file from which the even record was extracted. A COMPRESSED_EVENT 318 stores a value indicating whether the event record data was extracted from a compressed file. An FID 320 contains a string identifying a relay FID value of a relay associated with the circuit breaker to which the event record pertains.

A number of fields are provided that define parameters of the breaker event and the condition data acquired by the digital protective relay for the breaker associated with the recorded event. A SAMPLE_RATE 322 contains a value identifying a sample rate at which voltages of each phase were acquired during the breaker event. For example, an integer value is provided identifying the number of samples acquiring during each 60 Hz wave cycle. A value of 16 would correspond to 16 samples being acquired during each wave cycle. An EVENT_DTM 324 contains a date and time at which the breaker event was detected/recorded. A FILE_DTM 326 contains a date and time at which the file containing the breaker event data set was stored on the data collection server 230. A TEST_EVENT 328 contains an indicator regarding whether the event data is for a test event (i.e., a test of the protective digital relay logic/operation—an event having no bearing upon the physical wear on the circuit breaker).

A set of values are stored in the breaker event record that are used to calculate an effect that the breaker event had upon a remaining lifespan of the circuit breaker (or whether immediate proactive/remedial action is needed). An I2T_A 330 stores a calculated value (I2× Time duration) for phase A of the three phases of the circuit breaker during the breaker event. An I2T_B 332 stores a calculated value (I²× Time duration) for phase B of the three phases of the circuit breaker during the breaker event. An I2T_C 334 stores a calculated value (I²× Time duration) for phase C of the three phases of the circuit breaker during the breaker event. I-Squared-T or I²T (current squared, multiplied by time duration), is a measurement of an amount of energy interrupted per phase by the identified circuit breaker during the breaker trip event. For a discrete series of values, it is calculated (per phase) according to the following:

$${I}^{2} T = {\sum }_{k = t}^{n} {i [ k ]}^{2} \frac{1}{\frac{60}{r}}$$

$$where :$$

$$t = Sample index of the start of trip ,$$

$$n = Sample index of end of electrical trip ,$$

$$i [ k ] = Sample current value in Amps , and$$

$$r = Sample rate .$$

By way of example, the I2T value, provided on a per-phase basis, may be analyzed by service determination logic (executed by one or more of the proactive maintenance engine 250, the reactive maintenance engine 260, and other maintenance engine 270) to alternatively/additionally render a circuit breaker maintenance request for a particularly identified circuit breaker.

A MECH_TRIP_TIME 336 contains a value indicating the time required to trip the breaker. The time duration value of the mechanical trip time during a breaker trip event is defined, for example, as the number of (60 Hz) waveform cycles that pass from the instant in time at which the digital protective relay signals the circuit breaker to trip to the instant in time where the digital protective relay senses that the breaker has physically reached a fully open physical position. The MECH_TRIP_TIME provides a measure of a response speed of the physical actuation mechanism of the circuit breaker to initiation of the breaker trip by the associated digital protective relay. A relatively long duration contained in the MECH_TRIP_TIME 336 may indicate a lubrication problem or a problem with the breaker trip actuation mechanism.

An ELEC_TRIP_TIME 338 contains a value indicating the time required to arrest current flow through all phases of the digital protective relay during the breaker trip event. The time duration value of the electrical trip time during a breaker trip event is defined, for example, as the number of (60 Hz) waveform cycles that pass from the instant in time at which the digital protective relay signals the circuit breaker to trip to the instant in time where the digital protective relay senses that current for each of the phases is at (or near) zero amps for a sustained period of time (i.e. not oscillating). In that regard, the ELEC_TRIP_TIME 338 is the maximum of the three time durations stored for the respective phases (stored in ELECT_TRIP_TIME_A 340, ELECT_TRIP_TIME_B 342, ELECT_TRIP_TIME_C 344).

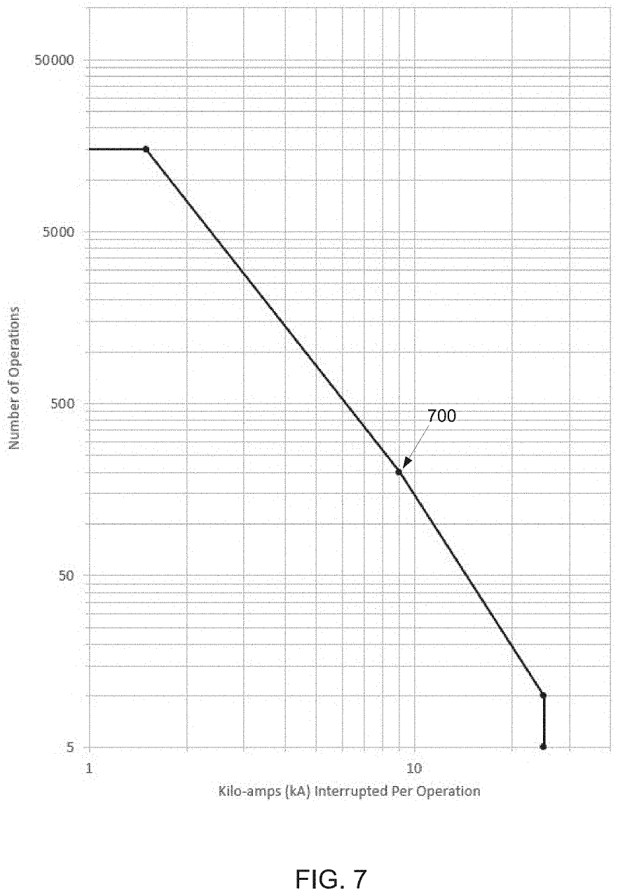

A fault magnitude value is generated and stored for each phase during the breaker event. The fault magnitude is the highest absolute current measured, on a per phase basis, after initiation of the breaker trip and before the end of the electrical trip event (i.e. the breaker is open and current is not flowing in any phase). The fault magnitude is analyzed by converting each phase current value array to absolute values and finding a maximum of the measured phase currents during the breaker trip event. A FAULT_MAG_A 350, a FAULT_MAG_B 352, and a FAULT_MAG_C 354 contain the recorded fault magnitudes for each of the three phases of the circuit breaker. The fault magnitude is a parameter value that can be used either alone, or in combination with other information maintained by the system to render circuit breaker maintenance/service alerts/requests. Alone, a single fault magnitude may be identified as exceeding a circuit failure alert limit for which immediate service is required. However, in other cases, the fault magnitude is substantially lower than the circuit failure alert limit, and in such case the fault magnitude is applied to a provided wear curve (see FIG. 7 described herein below) to update a percent wear associated with a single recorded circuit breaker trip event.

In an illustrative arrangement, a bank of batteries are maintained at substation that are in constant state of being charged and simultaneously providing power at a DC voltage (e.g. 120 volts) to both computer/processing components (e.g. digital protective relays and communication servers) and electrically powered circuit breaker actuators that trip circuit breakers (e.g. an electro-magnetically actuated latch that is actuated, by a DC actuation signal activated/issued by the digital protective relay, to release a circuit breaker from a closed state to an open state). A VDC_DROP 356 contains a magnitude of the voltage difference (drop) of the measured DC voltage, of the battery bank supplying the power to the DC actuation signal, between a desired DC voltage and a transient DC voltage of the battery bank output measured by the digital protective relay during the breaker event. A VDC_AVERAGE 358 contains an average DC (desired) voltage, over a relatively long time period, of the battery bank output powering the breaker actuator and the relays (controllers) themselves.

The VDC_DROP 356 and the VDC_AVERAGE 358 are used to determine a health status of the battery bank providing DC power to the circuit breaker actuators. By way of example, a maintenance alert is issued based upon a difference between: (1) the long-term DC voltage provided by the VDC_AVERAGE 358, and (2) a minimum instantaneous voltage of the DC output voltage of the battery bank output measured by the digital protective relay during the breaker event. By way of a specific example, an alert is raised in cases where the VDC_DROP 356 value exceeds 10 percent of the VDC_AVERAGE 358 value.

A set of wear values are assigned to each phase as a consequence of calculations performed on the measured currents and durations of the breaker trip event, on a per phase basis as PERCENT_WEAR_A 360, PERCENT_WEAR_B 362 and PERCENT_WEAR_C 364.

An ANALYZE_DTM 366 contains an identification of the date and time at which the above-described calculations associated with the breaker event were performed.

An OSCILLOGRAPHY 370 stores a Java Script Object Notation (JSON) oscillography object.

A SETTINGS 372 stores a JSON settings object.

An EVENT_DATA 374 stores a JSON event data object.

An OSC_PARSER_VERSION 376 contains an identification of the parser of the oscillography of the breaker event.

An ANALYZER_VERSION 378 contains a version number for the breaker metrics calculator that renders the above-described breaker event condition parameters indicative of the severity of the breaker event conditions.

An UPLOAD_DTM 380 contains an identification of the date and time at which the event record was tabled in the central data repository 200.

Turning to FIG. 4B, a set of exemplary fields are summarized for a wear curve set points table that is used to construct wear curves for performing percent-of-wear impact analyses for identified circuit breakers based upon the contents of the aforementioned breaker event data records discussed herein above with reference to FIG. 4A. A MANUFACTURER 400 contains a string identifying a manufacturer of the breaker. A MODEL 402 contains a string identifying a model of the breaker. A KV_RATING 404 contains a value specifying a kV rating for the breaker. A CONTINUOUS_AMP_RATING 406 contains a value specifying a continuous amperes rating for the breaker. An INTERRUPT_AMP_RATING 408 contains a value specifying an interrupt amperes rating. A KA_SETPOINT_1 410 contains a setpoint 1 kA value. A COUNT_SETPOINT_1 412 contains a setpoint 1 breaker trip operations count value. A KA_SETPOINT_2 414 contains a setpoint 2 kA value. A COUNT_SETPOINT_2 416 contains a setpoint 2 breaker trip operations count value. A KA_SETPOINT_3 418 contains a setpoint 3 kA value. A COUNT_SETPOINT_3 420 contains a setpoint 3 breaker trip operations count value.

A DATA_SOURCE 422 contains a data source identifier to mark generic wear curves or wear curves specified from a manufacturer of the breaker.

Turning to FIG. 4C, a set of exemplary fields are summarized for a custom breaker trip time limits table that is used to specify mechanical and electrical trip time limits for specified models of circuit breakers. A MODEL 430 contains a string identifying a model of the breaker. A MECH_TRIP_TIME_LIMIT 432 specifies a mechanical trip time limit such that a value for an actual trip time exceeding the time limit invokes issuance of an error condition and relating proactive/reactive/remedial action notifications. An ELEC_TRIP_TIME_LIMIT 434 specifies an electrical trip time limit such that a value for an actual trip time exceeding the time limit invokes issuance of an error condition and relating proactive/reactive/remedial action notifications.

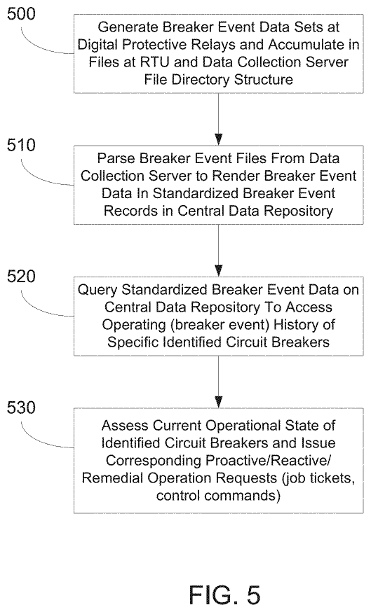

Turning to FIG. 5, a flowchart provides a summary of a set of operations performed by the system summarized in FIG. 3 to carry out automated building of circuit breaker event records in the central data repository 200 and analysis of the contents thereof in an automated circuit breaker maintenance infrastructure supporting, among other things, both proactive and reactive issuance of requests (job tickets) relating to an operating conditions-based maintenance facility for circuit breakers in an electrical power distribution infrastructure.

During 500, digital protective relays acquire breaker trip event data during occurrences of breaker events experienced by specific identified circuit breakers in an electrical power distribution infrastructure (see e.g., FIGS. 1 and 2A). The digital protective relays package the event data in files in a variety of formats and the files are thereafter forwarded to and stored within a directory structure maintained by the data collection server 230.

During 510 the breaker event data set parser 240 retrieves the breaker event data set files from the directory structure of the data collection server 230 and parses the contents of the files (provided in a variety of formats) to render/store the breaker event data sets for particular breaker events of particular identified circuit breakers, as identified breaker event data records provided in a standardized format in a breaker event table of the central data repository. Such parsing is carried out on a wide variety of file formats associated with particular manufacturers, models and versions of digital protective relays and/or circuit breakers. Such parsing includes, by way of example, extracting identification information arising from a directory position in the data collection server 230 from which the file was obtained, file name, file header information, decompression of compressed data files, oscillography data, identification of sampling rates, etc.

During 520, a maintenance engine (e.g. reactive maintenance engine 260) issues queries to the central data repository 200 requesting a set of data records meeting a particular circuit breaker identification to facilitate determination of a history of breaker events involving the particularly identified circuit breaker.

During 530 the maintenance engine applies decision logic to the set of data records obtained by the maintenance engine for the identified circuit breaker to assess a current operational state of the identified circuit breaker and renders/issues appropriate requests for actions (proactive, reactive, remedial, etc.) to be carried out on the identified circuit breaker. Further details of the above summarized operations are described herein below.

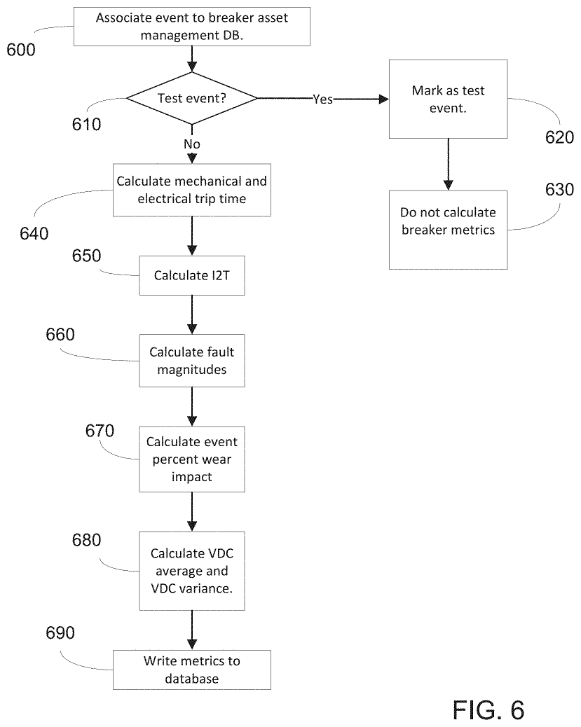

Turning to FIG. 6, a set of operations are summarized for an exemplary execution of operation 510 by the breaker event data set parser 240 to populate fields of a new circuit breaker event record. To extract values for rendering in the form of a standardized record format, by parsing a breaker event data set file, during 600 the file is initially associated with information about the particular circuit breaker upon which the breaker event occurred. In that regard, such association is facilitated by referring to an asset management database. The asset management database contains a table including a set of records corresponding to identified substations and associated circuit breakers. In that regard, the following data is provided for each circuit breaker: status (In Service, Retired, etc.); manufacturer; model; date installed/put in service; operating voltage; voltage rating; continuous current rating; interrupt rating. Using the facility name and operating point number extracted from a file name of a retrieved breaker event file, central data repository asset management database is queried on these values during file parsing to generate a uniquely identified new breaker event record. By way of example, a matching substation's facility ID (FAC_ID 306) and the breaker inventory item ID 312 values are copied from the asset management database to the event file data record for convenient reference during later processing (avoid a need to re-acquire such data when the breaker event record is retrieved at a later time during maintenance operations).

During the process of commissioning and installing relays, field personnel will perform several different test scenarios, where test equipment is hooked up to relay sensors and simulated fault conditions are presented to the relay to ensure it signals a trip as designed. During 610, the parser 240 determines whether the retrieved event file is for a test event (i.e. a simulated operation—as opposed to an actual tripping of the breaker). If the event is a test event, then control passes to 620 where the TEST_EVENT 328 is set to “true”—indicating the event file is associated with a simulated/test event that does not contribute in any appreciable way to wear upon the circuit breaker. Control passes to 630 wherein the new breaker event record is committed to the breaker event database of the central data repository 200 without calculating breaker metrics and without populating any fields relating to breaker event metrics (e.g. voltages, currents, time durations, etc.) associated with the breaker event.

On the other hand, if the retrieved event file is not for a test event (i.e. the circuit breaker was exposed to actual operational conditions and then tripped), control passes to 640 wherein the parser 240 extracts the detected event data to calculate and store mechanical and electrical trip time durations in appropriate fields of the new breaker event record (see FIG. 4A and associated written description provided above).

During 650 the parser 240 performs operations on data provided for each phase during the breaker event to render a measure of power flow during the duration of the breaker trip event and stores the resulting value in respective I2T fields of the event record (i.e., I2T_A 330, I2T_B 332, and I2T_C 334 described in detail herein above). To calculate the I2T metric, for each phase, a known trip start sample index and electrical trip end sample index are used and the formula is evaluated for samples between these two end points. The partial I2T results computed for each phase-specific current sample are summed to yield the phase-specific I2T value.

During 660 the parser 240 performs operation on data provided for each phase during the breaker event to render a fault magnitude for each phase. In that regard, the fault magnitude is defined as the highest absolute current value seen on a phase after start of trip and before end of electrical trip. It can be analyzed by converting each phase current value array to absolute values and finding a maximum magnitude following the start of trip sample index. Resulting values are stored in FAULT_MAG_A 350, FAULT_MAG_B 352, and FAULT_MAG_C 354 (See FIG. 4A).

During 670 the parser 240 calculates an incremental impact of the breaker event upon the projected lifetime of the circuit breaker. When a circuit breaker trips and interrupts current during a breaker event, the resultant heating and physical stress on the circuit breaker results in degradation of the physical (electrical and mechanical) state of electrical contacts of the identified circuit breaker. For example, physical degradation is present in the form of measurable/observable shortening of electrical conducting contacts of the circuit breaker. A manufacturer of the circuit breaker specifies a minimum length for proper operation of the circuit breaker—at which point at least the worn contacts need to be replaced, if not the entire circuit breaker given that other components of the circuit breaker are also subject to degradation over the course of operation of the circuit breaker during breaker trip events.

An estimate of contact wear for each phase of the circuit breaker is calculated, in accordance with the current disclosure, using a provided wear curve. In the illustrative example of a wear curve (see FIG. 7), a breaker wear curve comprises a log scale plot of the curve segments between a series of points. With reference to FIG. 7, a Y-axis indicates a number of breaker trip events/operations performed on the circuit breaker, and the X-axis indicates the kA (kiloamps) interrupted per operation. A 100 percent life curve is thereafter plotted on the chart to provide an indication of the cumulative effect of breaker trip events on the remaining life (percentage) of an identified circuit breaker. For example, the plotted wear curve can be used to determine the number of operations a breaker contact could withstand at a given kA value before reaching a fully worn out status. For example, according to point 700 on the depicted curve, the breaker described in the contact wear curve shown in FIG. 7 can be tripped 200 times at a 9 kA fault magnitude before being considered fully worn.

To generate a wear curve for a particular identified circuit breaker (for purposes of generating a percentage of wear for a particular breaker trip event, specific set points (X,Y coordinates) are for a particular identified manufacturer and identified breaker model, voltage rating, continuous amp rating, and interrupt rating. These set points are stored within a static database table for reference by the parser 240 during processing the breaker event data set to render incremental wear (e.g. percent of lifetime consumed) during 670. By way of example, the FAULT_MAG for each phase (A, B, and C) are applied to the wear curve (see e.g., FIG. 7) to render a corresponding number of close/open operations that correspond to 100 percent use. Thereafter, an incremental percentage of wear on the contacts for the indicated phase is calculated as follows:

$$Phase Percent Wear = \frac{1}{Possible Operations at Fault Magnitude} ⋆ 100$$

In order to calculate the possible operations at a fault magnitude value, the corresponding wear curve segment must be evaluated for an X value to yield a Y value.

Before solving a curve segment for Y, two simple edge cases can be considered:

If the fault magnitude kA value is at or above the kA value of the final setpoint (the setpoint with the highest kA value), the event has an immediate 100% wear impact.

If the fault magnitude kA value is at or below the kA value of the first setpoint (the setpoint with the lowest kA value), the number of possible operations is equal to the Y coordinate of that setpoint.

If the fault magnitude value comparison does not meet these criteria, the analysis process finds the setpoints where the fault magnitude value falls between. On these curve segments, the number of possible operations for a given fault magnitude can be expressed in a fashion similar to the standard linear slope-intercept form:

y=x^{m}*b

Where m is analogous to a linear slope and b is analogous to a linear intercept.

To solve for m:

$$m = {log}_{\frac{{x}_{1}}{{x}_{2}}} \frac{{y}_{1}}{{y}_{2}}$$

Where X1 and X2 are the kA values of the two segment setpoints and Y1 and Y2 are the number of possible operations for the two setpoints.

After solving for m, it is now possible to solve for b:

$$b = \frac{{y}_{2}}{{x}_{2}^{m}}$$

Where Y2 and X2 are the number of operations and kA values for the second segment setpoint.

Expressing this as a unified equation:

$$Phase Percent Wear = \frac{1}{{( k {A}_{Fault} )}^{m} * b} * 100$$

During 670 the parser runs the calculations for each event provided a fault magnitude and breaker wear curve set points are found. This produces per phase breaker contact wear impact percentage values that are saved to Percent_Wear_A360, Percent_Wear_B 362, and the Percent_Wear_C 364 for the respective phases of the identified breaker event record. Thereafter, maintenance engines 250, 260 and 270 run simple queries on the central data repository to obtain all records associated with the identified circuit breaker and calculating a remaining life for circuit breaker contacts (on a per phase basis) by summing the percentage of wear values stored in each of the respective phases/fields 360, 362 and 364.

In some cases, a breaker's controlling relay may operate for many years without being connected to an RTU unit. This prevents event files from being pulled from the relay and the internal storage of the relay will eventually fill with event files, causing old files to be overwritten. When an RTU is later installed at the location, event files begin to flow over the network, but there is a gap in the overall data set for that breaker. To account for this, the asset management database is queried to see if the first recorded event file occurred after the breaker install date. If a missing time gap is identified, the wear for this time period is estimated as:

$$Estimated Wear = \frac{Total Calculated Phase Wear}{Days Since First Trip Event} ⋆ Days From Breaker Install to First Trip Event$$

Estimated wear is added to total calculated phase wear to give a reasonable estimate of total phase wear on breakers missing event file data.

During 680 the parser 240 calculates a value for storing in the VDC_Drop 356 and the VDC_Average 358 for the identified breaker event record. By way of background, for breakers, a digital protective relay sends a DC signal to activate a circuit breaker trip coil to initiate a trip of a circuit breaker. The DC signal typically comes from the substation's (continuously recharging) battery bank. When the load of the breaker trip (electro-magnetic) coil is applied to the batteries by command from the corresponding digital protective relay, the DC voltage drops (transiently) and quickly recovers after the breaker trip coil actuates a mechanical latch causing release of the latch holding the circuit breaker in a closed state. The digital protective relay measures DC voltages during circuit breaker events since the batteries are the power source for (actuating/releasing the latch) tripping the circuit breaker, and a voltage drop (also referred to as variance), from a long-term average DC voltage output of the battery bank, that is too high indicates a potential problem with the DC signal power source (e.g., battery bank) supplying sufficient electrical power to actuate the latch to open the circuit breaker.

During 680, the parser 240 calculates a DC average voltage value (for VDC_Average 358) by taking the average of all DC voltage values in the associated JSON array for the entire event. Additionally, during 680 the parser computes a DC voltage variance (or voltage drop) as follows:

VDC Variance=Max(VDC)−Min(VDC)

During 690 the parser 240 commits the newly generated parameter (metrics) values for the identified breaker event record in the central data repository 200.

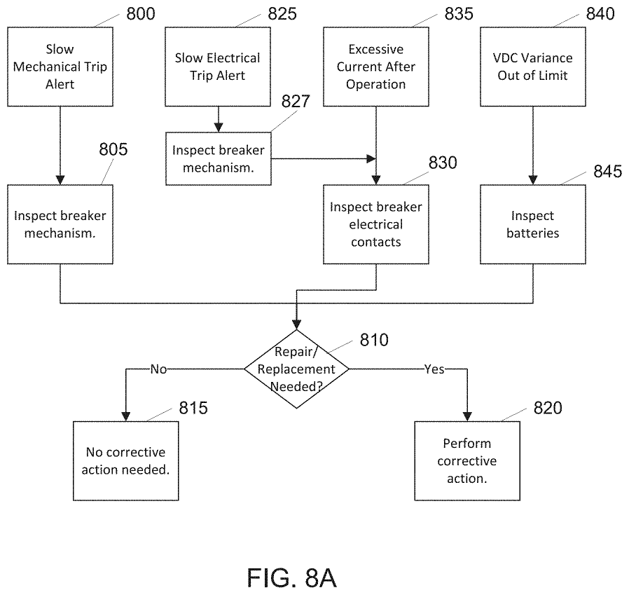

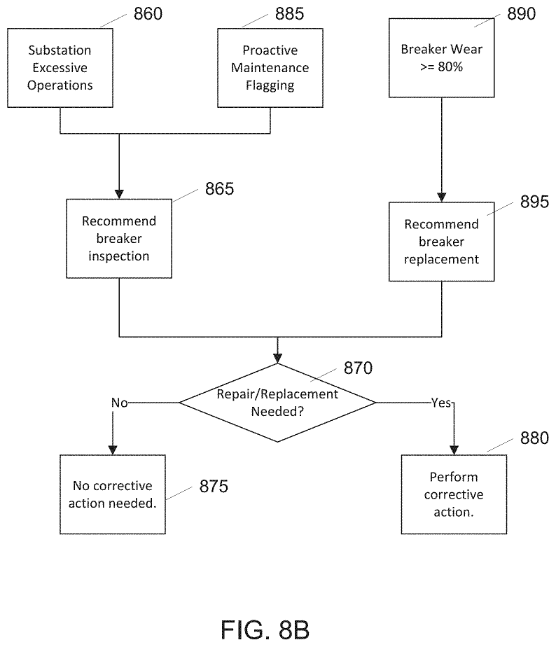

Having described the database supplying function performed by the parser 240 with respect to the breaker event records maintained in the central data repository 200, attention is directed to FIGS. 8A and 8B that summarize proactive and reactive breaker event record data consuming operations carried out by, for example the maintenance engines 250, 260 and 270 in the exemplary arrangement schematically depicted in FIG. 3.

Turning to FIG. 8A, operation of the reactive maintenance engine 260 is directed to providing maintenance-related requests and notifications with regard to maintenance operations that need relatively urgent/prompt attention to avoid/address a circuit breaker malfunction. The decision-making of the reactive maintenance engine with respect to a particular circuit breaker is driven by the content of data records corresponding to the particular identified circuit breaker that is provided by the central data repository 200 database in response to queries submitted by the reactive maintenance engine 260.

The reactive maintenance engine 260 processes the breaker event records for circuit breakers on an individually identified breaker basis, and issues alerts/job tickets/automated action requests to appropriate recipients in accordance with determining a breaker health status metric indicates a need for repair/replacement of a circuit breaker or a related component. Given the automated nature of components in the disclosed system, such requests/messages are generated/issued with minimal delay (e.g. within 10 to 20 minutes of occurrence of a breaker event from which a condition is detected for which repair/replacement of a circuit breaker is needed.

For alerts relating to mechanical or electrical trip times, a static database table exists to specify custom trip time limits for certain breaker models. If a breaker model is not found on this table, a default trip time limit is used. As indicated by FIG. 4C, the system contemplates specification of custom trip time limits for identified circuit breaker models.

With reference to FIG. 8A a slow mechanical trip condition is potentially detected by the reactive maintenance engine 260 during 800, and control passes to 805 wherein a message/job ticket is issued to initiate inspecting, testing, repairing, and/or replacing (via automated and/or human action) of the physical breaker mechanical hardware. Such messaging/job ticket issuance may occur in any of a variety of manners, including email, text message, process control command, etc. By way of a particular, example, the reactive maintenance engine 260 analyzes a value for mechanical trip time taken from the Mech_Trip_Time 336 for an identified circuit breaker event record, and the engine 260 issues an alert via email to maintenance services in accordance with determining a mechanical trip time for the identified circuit breaker exceeds 4 cycles (default) or a customized mechanical trip time for the identified model of the circuit breaker retrieved from the customized trip time table (see FIG. 4C, Mech_Trip_Time_Limit 432).

The mechanical trip time alert message/job ticket, triggers initiating a substation maintenance crew or equipment specialist to inspect a physical actuation mechanical component of the identified circuit breaker and perform repairs or a replacement if necessary in accordance with operations 810, 815 and 820.

With continued reference to FIG. 8A, a slow electrical trip condition is potentially detected by the reactive maintenance engine 260 during 825, and control passes to 827 wherein a message/job ticket is issued to initiate inspection, testing, repair, or replacement (either automated or human) of the physical breaker mechanical hardware. Additionally, during 830 the reactive maintenance engine further issues (in a same or separate message/job ticket as the one issued during 827) a request/command to initiate inspecting, testing, repairing, and/or replacing (via either automated and/or human action) of the electrical contacts of the breaker hardware. Such messaging/job ticket issuance may occur in any of a variety of manners, including email, text message, process control command, etc. By way of a particular, example, the reactive maintenance engine 260 analyzes a value for electrical trip time taken from the Elec_Trip_Time 338 (the maximum value of the three delay values stored for the individual phases stored in 340, 342 and 344) for an identified circuit breaker event record, and the reactive maintenance engine 260 issues an alert via email to maintenance services in accordance with determining an electrical trip time for the identified circuit breaker exceeds 5 cycles (default) or a customized electrical trip time for the identified model of the circuit breaker retrieved from the customized trip time table (see FIG. 4C, Elec_Trip_Time_Limit 434).

The electrical trip time alert message/job ticket, triggers initiating a substation maintenance crew or equipment specialist to inspect electrical contacts of the identified circuit breaker for excessive wear (shortening) and perform repairs or a replacement if necessary in accordance with operations 810, 815 and 820.

With further reference to FIG. 8A, an excessive current flow after the mechanical switch of the circuit breaker is fully open. As such excess duration of current flow is potentially detected by the reactive maintenance engine 260 during 835, and control passes to 830 for further processing in accordance with the description provided herein above. In a particular example, an excessive delay condition threshold is an electrical delay specified in Elec_Trip_Time 338 that persists 3.5 cycles longer than the mechanical trip time specified in Mech_Trip_Time 336. Usually, events that trigger this alert also trigger a slow electrical trip alert but may not in cases where the mechanical trip time and electrical trip time are both under their slow trip limits (for example, a mechanical trip time of 1.5 cycles and an electrical trip time of 5 cycles). This alert indicates the mechanical breaker operation is ineffective in interrupting current. Like the slow electrical trip alert, it would also trigger a decision to send personnel to inspect the breaker contacts in accordance with operations 810, 815 and 820.

In accordance with operation 840, the reactive maintenance engine 260 is configured to determine that a variance of a DC signal from the digital protective relay to the identified circuit breaker is outside of an acceptable range. Therefore, in the event that the variance of the observed DC voltage exceeds a specified threshold, the reactive maintenance engine issues an alert/message/request to initiate inspection/testing of batteries providing power for the DC signal issued by the relay to the circuit breaker during 845. By way of a specific example, an error condition is determined to exist, requiring remedial action (e.g., repairing/replacing the power source—in this case the batteries) upon determining that the variance (see VDC_variance 356) is more than 10 percent of the average DC voltage (see VDC_Average 358). The alert/message triggers a decision to send a battery specialist to inspect the battery system at the substation and make repairs or replacements of the batteries as needed.

The alerts/messages issued by the reactive maintenance engine 260 may be provided in any of a variety of forms. By way of example, such alerts/messages contain helpful information about the relay, breaker, event, and the limit that was exceeded.

Turning to FIG. 8B, operation of the proactive maintenance engine 250 is directed to providing maintenance-related requests and notifications with regard to maintenance operations that need relatively less urgent/prompt attention to maintain reliable/expected circuit breaker operation and thereby avoid rushed response to prevent a circuit breaker malfunction. The decision-making of the proactive maintenance engine 250 with respect to a particular circuit breaker (or group of circuit breakers within a same substation of interest) is driven by the content of data records corresponding to the particular identified circuit breaker(s) that is provided by the central data repository 200 database in response to queries submitted by the proactive maintenance engine 260.

In accordance with the operations summarized in FIG. 8B, a proactive maintenance engine 250 operates alongside the reactive maintenance engine 260 to execute, on a relatively lower level of urgency—though still in near real-time (with respect to an instance of a breaker event), automated repeating and/or on-demand reporting processes producing additional intelligence regarding breaker or substation conditions. By way of example, upon passage of a severe storm through an area, the proactive maintenance engine 250 accesses breaker event records corresponding to substations within the area over which the storm passed. The accessed records are likely to reveal excessive (increased) rates for breaker events occurring during passage of the storm due to lightning strikes.

The same data source allows for a comparison of this value with the number of operations averaged across all days where event file data was present. During 860, the proactive maintenance engine 250 flags a circuit breaker if the breaker trip rate for the substation (including multiple relays/circuit breakers—taken in the aggregate) exceeds the higher of two breaker event instances limits:

1. Breaker trips on a given day was greater than or equal to 10;

2. Breaker trips on a given day was over 200% of normal.

When a substation is flagged, during 865 the proactive maintenance engine 250 issues a request/alert/job ticket causing a substation maintenance crew to visit and inspect the entire substation housing the relays/breakers of interest for damage, including the breakers themselves. In accordance with 870, 875 and 880, maintenance is performed on an as-needed basis. Importantly, the alert/request issuance is based upon detected conditions at the circuit breakers—as opposed to the knowledge that bad weather passed over the area containing the substation of interest.

During 890, the proactive maintenance engine 250 performs operations on a complete set of breaker events detected for a particular identified circuit breaker to identify when conditions indicate that excessive wear is present in the particular identified circuit breaker. By way of example, during 890, the proactive maintenance engine 250 assigns an end-of-life status to the particular identified circuit breaker when the cumulative/incremental wear for any one of the three phases, calculated by summing the percentages stored in percent wear fields 360, 362 or 364 (including an estimate for instances where such information was previously unavailable), registers at least 80 percent. In such case, during 895 the proactive maintenance engine 250 issues an alert/request to schedule replacement of the identified circuit breaker without any prior in-person inspection of the circuit breakers of interest.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein known to the inventors for carrying out the invention. Variations of these embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method for maintaining circuit breakers in an electrical power distribution infrastructure based upon recorded operating conditions during breaker trip events of particularly identified circuit breakers, the method comprising:
generating breaker event data set files comprising operating conditions recorded by associated digital protective relays, on an individual circuit breaker basis, during circuit breaker trip events by identified circuit breakers;
parsing the breaker event data set files to render breaker event records:
maintained in a standardized breaker event record format, and
comprising operating conditions recorded by associated digital protective relays during breaker events;
tabling the breaker event records in a data repository;
executing a query upon the data repository to retrieve particular breaker event field data from breaker event records in the data repository corresponding to an identified circuit breaker; and
rendering a circuit breaker maintenance request for the identified circuit breaker in accordance with executing circuit breaker logic for performing an analysis of breaker event field data acquired from breaker event records corresponding to the identified circuit breaker during the executing a query.

2. The method of claim 1 wherein the circuit breaker logic performs the analysis based additionally upon information for a particular identified circuit breaker acquired from an asset management database comprising records corresponding to individual circuit breakers.

3. The method of claim 1 wherein the parsing comprises determining a circuit breaker identification for a particular circuit breaker corresponding to a breaker event data set file based upon information provided by:
the breaker event data set file, and
an asset management database comprising records corresponding to individual circuit breakers.

4. The method of claim 1 wherein the rendering a circuit breaker maintenance request is based upon a value of a circuit breaker fault current magnitude obtained from a breaker event record derived from a breaker event data set file for the identified circuit breaker.

5. The method of claim 4, wherein, during the rendering, the value of the circuit breaker fault current magnitude is applied to a circuit breaker wear curve corresponding to the identified circuit breaker.

6. The method of claim 4, wherein the value of the circuit breaker fault current magnitude is provided for a specific phase of an electrical power supply passing through the identified circuit breaker.

7. The method of claim 1 wherein the rendering a circuit breaker maintenance request is based upon a value of a time duration parameter obtained from a breaker event record derived from a breaker event data set file, wherein the time duration parameter is taken from the group consisting of:
a mechanical trip time; and
an electrical trip time.

8. The method of claim 1 further comprising rendering a battery maintenance request for a battery that powers a trip circuit for the identified circuit breaker based upon a battery status parameter for which values are acquired and reported in association with the breaker event.

9. The method of claim 8, wherein the battery maintenance request is based upon at least a direct current voltage drop recorded during a circuit breaker trip event.

10. The method of claim 9, wherein the battery maintenance request is based upon the direct current voltage drop and an average direct current voltage of the battery.

11. A networked system including:
a network communications interface;
a processor; and
a non-transitory computer readable medium including computer-executable instructions that, when executed by the processor, facilitate carrying out a method for maintaining circuit breakers in an electrical power distribution infrastructure based upon recorded operating conditions during breaker trip events of particularly identified circuit breakers, the method comprising:
generating breaker event data set files comprising operating conditions recorded by associated digital protective relays, on an individual circuit breaker basis, during circuit breaker trip events by identified circuit breakers;
parsing the breaker event data set files to render breaker event records:
maintained in a standardized breaker event record format, and
comprising operating conditions recorded by associated digital protective relays during breaker events;
tabling the breaker event records in a data repository;
executing a query upon the data repository to retrieve particular breaker event field data from breaker event records in the data repository corresponding to an identified circuit breaker; and
rendering a circuit breaker maintenance request for the identified circuit breaker in accordance with executing circuit breaker logic for performing an analysis of breaker event field data acquired from breaker event records corresponding to the identified circuit breaker during the executing a query.

12. The system of claim 11 wherein the circuit breaker logic performs the analysis based additionally upon information for a particular identified circuit breaker acquired from an asset management database comprising records corresponding to individual circuit breakers.

13. The system of claim 11 wherein the parsing comprises determining a circuit breaker identification for a particular circuit breaker corresponding to a breaker event data set file based upon information provided by:
the breaker event data set file, and
an asset management database comprising records corresponding to individual circuit breakers.

14. The system of claim 11 wherein the rendering a circuit breaker maintenance request is based upon a value of a circuit breaker fault current magnitude obtained from a breaker event record derived from a breaker event data set file for the identified circuit breaker.

15. The system of claim 14, wherein, during the rendering, the value of the circuit breaker fault current magnitude is applied to a circuit breaker wear curve corresponding to the identified circuit breaker.

16. The system of claim 14, wherein the value of the circuit breaker fault current magnitude is provided for a specific phase of an electrical power supply passing through the identified circuit breaker.

17. The system of claim 11 wherein the rendering a circuit breaker maintenance request is based upon a value of a time duration parameter obtained from a breaker event record derived from a breaker event data set file, wherein the time duration parameter is taken from the group consisting of:
a mechanical trip time; and
an electrical trip time.

18. The system of claim 11 wherein the method further comprises rendering a battery maintenance request for a battery that powers a trip circuit for the identified circuit breaker based upon a battery status parameter for which values are acquired and reported in association with the breaker event.

19. The system of claim 18, wherein the battery maintenance request is based upon at least a direct current voltage drop recorded during a circuit breaker trip event.

20. The system of claim 19, wherein the battery maintenance request is based upon the direct current voltage drop and an average direct current voltage of the battery.
